(19) United States
(12) Patent Application Publication
(10) Pub. No.: US 2026/0371810 A1
(43) Pub. Date: Nov. 19, 2026

(54) DISPLAY DEVICE

(71) Applicant: LG Display Co., Ltd., Seoul (KR)

(72) Inventor: Sungmoo KIM, Goyang-si (KR)

(21) Appl. No.: 19/635,706

(22) Filed: Mar. 31, 2026

(30) Foreign Application Priority Data
May 16, 2025 (KR) 10-2025-0063858

(51) Int. Cl. H10H 29/34; H10H 29/37; H10H 29/41; H10H 29/80; H10H 29/851

(52) U.S. Cl. CPC H10H 29/345; H10H 29/37; H10H 29/41; H10H 29/8515; H10H 29/882

(57) ABSTRACT

A display device including a plurality of light emitting elements disposed in each of a plurality of sub pixels, and a bank disposed between the plurality of sub pixels and including a plurality of open areas overlapping the plurality of light emitting elements, in which a light emitting element of a red sub pixel is disposed at a lower elevation than light emitting elements of a green sub pixel and a blue sub pixel, and a size of the open area of the red sub pixel is greater than open areas of the green sub pixel and the blue sub pixel.

### CROSS REFERENCE TO RELATED APPLICATION

This application claims priority from and the benefit of Korean Patent Application

No. 10-2025-0063858, filed on May 16, 2026, which is hereby incorporated by reference for all purposes as if fully set forth herein.

### BACKGROUND

### Field

Embodiments of the invention relate generally to a display device, and more particularly, to a display device employing a light emitting diode (LED).

### Discussion Of The Background

Display devices used for a monitor of a computer, a TV, or a mobile phone may typically include an organic light emitting display (OLED) that emits light by itself, or a liquid crystal display (LCD) that requires a separate light source.

Display devices have been applied in a variety of applications, including computer monitors, TVs, and personal portable devices. Accordingly, research is being conducted on display devices that have a large display area while maintaining reduced volume and weight.

Recently, a display device including an LED is attracting attention as a next-generation display device. Since the LED is made of an inorganic material rather than an organic material, it exhibits excellent reliability and has longer lifespan than those of a liquid crystal display device or an organic light emitting display device. In addition, the LED has a fast response speed, excellent luminous efficiency, and a strong impact resistance, thereby providing improved stability and enabling display of high luminance images.

The above information disclosed in this Background section is only for understanding of the background of the inventive concepts, and, therefore, it may contain information that does not constitute prior art.

### SUMMARY

Display devices according to embodiments of the invention are capable of displaying high-resolution images.

Display devices according to embodiments of the invention are capable of providing improved light conversion efficiency of a light conversion layer.

Display devices according to embodiments of the invention are capable of maintaining the same viewing angles across a plurality of sub pixels.

Display devices according to embodiments of the invention are capable of enabling a reduction in size of at least some of a plurality of sub pixels.

Display devices according to embodiments of the invention are capable of forming a light conversion layer having an appropriate thickness.

Additional features of the inventive concepts will be set forth in the description which follows, and in part will be apparent from the description, or may be learned by practice of the inventive concepts.

A display device according to an embodiment of the invention includes a substrate on which a plurality of sub pixels including a red sub pixel, a green sub pixel, and a blue sub pixel is defined, a TFT array disposed on the substrate, a plurality of light emitting elements disposed on the TFT array in each of the plurality of sub pixels, and a bank disposed between the plurality of sub pixels and including a plurality of open areas overlapping the plurality of light emitting elements, in which a light emitting element of the red sub pixel among the plurality of light emitting elements is disposed at a lower elevation than light emitting elements of the green sub pixel and the blue sub pixel, and a size of an open area of the red sub pixel among the plurality of open areas is greater than a size of an open area of each of the green sub pixel and the blue sub pixel.

The size of the open area of the green sub pixel and the size of the open area of the blue sub pixel may be substantially the same.

The plurality of light emitting elements may include a first light emitting element disposed in the red sub pixel and the blue sub pixel and configured to emit blue light, and a second light emitting element disposed in the green sub pixel and configured to emit green light.

The display device may further include a first pixel electrode disposed between the TFT array and the plurality of light emitting elements in each of the plurality of sub pixels, a first planarization layer disposed on the first pixel electrode, a common electrode disposed on the first planarization layer in each of the plurality of sub pixels, a second planarization layer disposed on the common electrode, and a second pixel electrode disposed on the second planarization layer in the green sub pixel and the blue sub pixel.

In the red sub pixel, the first light emitting element may be disposed between the first pixel electrode and the common electrode, and may be surrounded by the first planarization layer.

Each of the second light emitting element of the green sub pixel and the first light emitting element of the blue sub pixel may be disposed between the common electrode and the second pixel electrode, and may be surrounded by the second planarization layer.

Each of the second light emitting element of the green sub pixel and the first light emitting element of the blue sub pixel may be disposed at a higher elevation than the first light emitting element of the red sub pixel, and may be disposed closer to an upper end of the bank.

A range of a viewing angle over which light is emitted from each of the first light emitting element of the red sub pixel, the second light emitting element of the green sub pixel, and the first light emitting element of the blue sub pixel may be substantially the same.

The first light emitting element may include a first n-type electrode, a first n-type semiconductor layer on one surface of the first n-type electrode, a first emission layer on one surface of the first n-type semiconductor layer, a first p-type semiconductor layer on one surface of the first emission layer, and a first p-type electrode on one surface of the first p-type semiconductor layer, in which the first n-type electrode of the first light emitting element of the red sub pixel may be electrically connected to the common electrode, and the first p-type electrode of the first light emitting element of the red sub pixel may be electrically connected to the first pixel electrode, and in which the first n-type electrode of the first light emitting element of the blue sub pixel may be electrically connected to the common electrode, and the first p-type electrode of the first light emitting element of the blue sub pixel may be electrically connected to the second pixel electrode.

The first n-type electrode, the first n-type semiconductor layer, the first emission layer, the first p-type semiconductor layer, and the first p-type electrode in the red sub pixel may be stacked in a reverse order from those in the blue sub pixel.

The display device may further include a light conversion layer disposed on the second planarization layer in the red sub pixel, and a scattering layer disposed on the second planarization layer in the green sub pixel and the blue sub pixel.

The second planarization layer may include a 2-1-th planarization layer disposed in the green sub pixel and the blue sub pixel, a 2-2-th planarization layer disposed in the red sub pixel, in which a thickness of the 2-1-th planarization layer may be greater than a thickness of the 2-2-th planarization layer.

The light conversion layer and the scattering layer may be disposed in a space between the banks, and a thickness of the light conversion layer may be greater than a thickness of the scattering layer.

The bank may include a first bank extending in a first direction between the plurality of sub pixels, and a second bank disposed on the first bank and the TFT array and extending between the plurality of sub pixels in the first direction and a second direction different from the first direction, in which the first bank may be disposed between the first planarization layers of the plurality of sub pixels, and the second bank may be disposed to surround the first planarization layer, the second planarization layer, the light conversion layer, and the scattering layer of the plurality of sub pixels.

A display device according to another embodiment of the invention includes a first sub pixel, a second sub pixel, and a third sub pixel configured to emit light of a different color and each including a light emitting element, a first electrode disposed on the light emitting elements of the first, second, and third sub pixels, a planarization layer disposed on the first electrode, in which a thickness of the planarization layer disposed in the second sub pixel is less than that of the planarization layer disposed in the first and third sub pixels, and a width of the planarization layer disposed in the second sub pixel is greater than that of the planarization layer disposed in the first and third sub pixels.

The planarization layer of the second sub pixel may be spaced apart from the light emitting element of the second sub pixel, and the planarization layer of the first sub pixel is disposed on a same plane as the light emitting element of the first sub pixel.

The light emitting elements of the first and second sub pixels may be respectively disposed on opposing surfaces of the first electrode.

The display device may further include a light conversion layer disposed on the planarization layer of the second sub pixel, in which the light conversion layer may have a thickness greater than that of the planarization layer of the first sub pixel.

It is to be understood that both the foregoing general description and the following detailed description are exemplary and explanatory and are intended to provide further explanation of the invention as claimed.

### BRIEF DESCRIPTION OF DRAWINGS

The accompanying drawings, which are included to provide a further understanding of the invention and are incorporated in and constitute a part of this specification, illustrate embodiments of the invention, and together with the description serve to explain the inventive concepts.

FIG. 1 is a schematic block diagram of a display device according to an embodiment of the invention.

FIG. 2 is a partial cross-sectional view of a display device according to an embodiment of the invention.

FIG. 3 is a schematic enlarged plan view of a display area of a display device according to an embodiment of the invention.

FIG. 4 is a schematic enlarged plan view of a display area of a display device according to an embodiment of the invention.

FIG. 5 is a cross-sectional view of a blue sub pixel taken along line A-A′ in FIG. 3.

FIG. 6 is a cross-sectional view of a red sub pixel taken along line B-B′ in FIG. 3.

FIG. 7 is a cross-sectional view of a green sub pixel taken along line C-C′ in FIG. 3.

FIG. 8 is a schematic cross-sectional view of a plurality of sub pixels taken along line D-D′ in FIG. 3.

### DETAILED DESCRIPTION

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods employing one or more of the inventive concepts disclosed herein. It is apparent, however, that various embodiments may be practiced without these specific details or with one or more equivalent arrangements. In other instances, well-known structures and devices are shown in block diagram form in order to avoid unnecessarily obscuring various embodiments. Further, various embodiments may be different, but do not have to be exclusive. For example, specific shapes, configurations, and characteristics of an embodiment may be used or implemented in another embodiment without departing from the inventive concepts.

Unless otherwise specified, the illustrated embodiments are to be understood as providing features of varying detail of some ways in which the inventive concepts may be implemented in practice. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the D1-axis, the D2-axis, and the D3-axis are not limited to three axes of a rectangular coordinate system, such as the x, y, and z-axes, and may be interpreted in a broader sense. For example, the D1-axis, the D2-axis, and the D3-axis may be perpendicular to one another, or may represent different directions that are not perpendicular to one another. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of idealized embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the inventive concepts. Further, the blocks, units, and/or modules of some embodiments may be physically combined into more complex blocks, units, and/or modules without departing from the scope of the inventive concepts.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and should not be interpreted in an idealized or overly formal sense, unless expressly so defined herein.

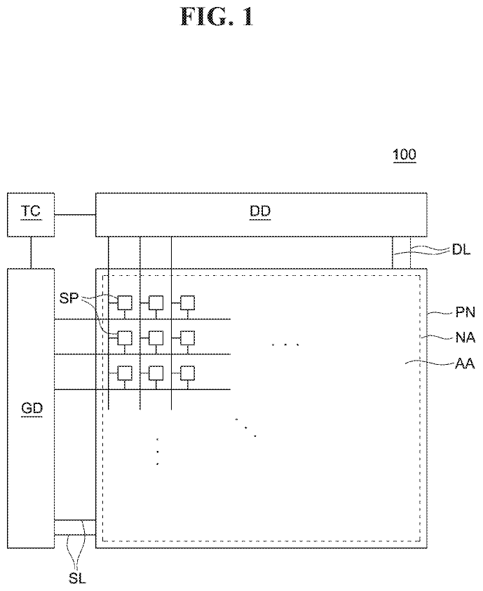

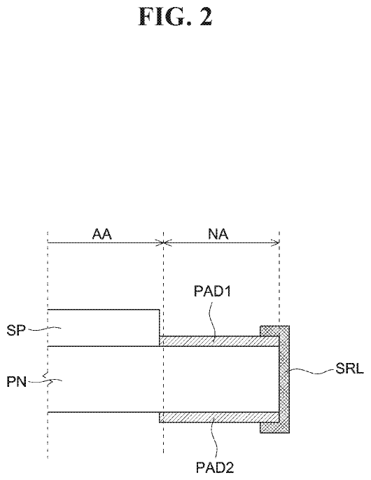

FIG. 1 is a schematic block diagram of a display device according to an embodiment. FIG. 2 is a partial cross-sectional view of a display device according to an embodiment. In FIG. 1, for the convenience of description, among various components of the display device 100, only a display panel PN, a gate driver GD, a data driver DD, and a timing controller TC are illustrated.

Referring to FIG. 1, a display device 100 according to an embodiment includes a display panel PN including a plurality of sub pixels SP, a gate driver GD and a data driver DD for supplying various signals to the display panel PN, and a timing controller TC for controlling the gate driver GD and the data driver DD.

The gate driver GD may supply a plurality of scan signals to a plurality of scan lines SL according to a plurality of gate control signals provided from the timing controller TC. FIG. 1 exemplarily illustrates that one gate driver GD is disposed to be spaced apart from one side of the display panel PN, however, the inventive concepts are not limited to a particular number or a specific arrangement of the gate driver GD.

The data driver DD may supply a data voltage to a plurality of data lines DL according to a plurality of data control signals and image data provided from the timing controller TC. The data driver DD may convert image data into a data voltage using a reference gamma voltage, and supply the converted data voltage to a plurality of data lines DL.

The timing controller TC may align image data input from the outside and supply the image data to the data driver DD. The timing controller TC may generate a gate control signal and a data control signal by using a synchronization signal input from the outside, for example, a dot clock signal, a data enable signal, and a horizontal/vertical synchronization signal. Further, the timing controller TC may supply the generated gate control signal and data control signal to the gate driver GD and the data driver DD, respectively, to control the gate driver GD and the data driver DD.

The display panel PN is configured to display images to a user and includes a plurality of sub pixels SP. In the display panel PN, the plurality of scan lines SL and the plurality of data lines DL may cross each other, and the plurality of sub pixels SP may be formed at intersections of the scan line SL and the data line DL.

The display panel PN may include a display area AA and a non-display area NA.

The display area AA may be defined as an area in which images are displayed in the display device 100. In the display area AA, a plurality of sub pixels SP constituting a plurality of pixels and a pixel circuit for driving the plurality of sub pixels SP may be disposed. The plurality of sub pixels SP may be a minimum unit constituting the display area AA, and ‘n’ sub pixels SP may form one pixel, in which ‘n’ is a natural number. A circuit for driving the plurality of light emitting elements ED may be disposed in each of the plurality of sub pixels SP. The plurality of light emitting elements ED may be configured differently depending on the type of the display panel PN. For example, when the display panel PN is an inorganic light emitting display panel PN, the light emitting element ED may be a light emitting diode (LED) or a micro light emitting diode (micro LED).

In the display area AA, a plurality of signal lines for transmitting various signals to the plurality of sub pixels SP may be disposed. For example, the plurality of signal lines may include a plurality of data lines DL which supplies a data voltage to each of the plurality of sub pixels SP, a plurality of scan lines SL which supplies a scan signal to each of the plurality of sub pixels SP, and the like. The plurality of scan lines SL may extend in one direction in the display area AA and be electrically connected to the plurality of sub pixels SP, and the plurality of data lines DL may extend in a direction different from the one direction in the display area AA and be electrically connected to the plurality of sub pixels SP. In addition, a power line, a reference line, and the like may further be disposed in the display area AA, without being limited thereto.

The non-display area NA may be defined as an area where images are not displayed and may extend from the display area AA. In the non-display area NA, a link line and a pad electrode for transmitting a signal to the sub pixel SP of the display area AA, or a driving IC, such as a gate driver IC or a data driver IC, may be disposed. The non-display area NA may be located on a rear surface of the display panel PN, that is, a surface on which the sub pixels SP are not disposed or the non-display area NA may be omitted, and is not limited to the configuration illustrated in the drawing.

A driver such as a gate driver GD, a data driver DD, and a timing controller TC may be electrically connected to the display panel PN in various ways. For example, the gate driver GD may be mounted in the non-display area NA in a gate-in-panel (GIP) manner or mounted between the plurality of sub pixels SP in the display area AA in a gate-in-display area (GIA) manner.

For example, the data driver DD and the timing controller TC may be formed on separate flexible films and printed circuit boards. Further, the display panel PN, the data driver DD, and the timing controller TC may be electrically connected by bonding the flexible film and the printed circuit board to the pad electrode formed in the non-display area NA of the display panel PN.

As another example, when the gate driver GD is mounted in the display area AA in the GIA manner, the flexible film and the printed circuit board may be bonded the pad electrode on the rear surface of the display panel PN. Further, a side line SRL may be formed to electrically connect the signal line on the front surface of the display panel PN to the pad electrode on the rear surface of the display panel PN. Accordingly, the non-display area NA on the front surface of the display panel PN may be minimized or at least be reduced. Therefore, when the gate driver GD, the data driver DD, and the timing controller TC are electrically connected to the display panel PN in the above-described manner, a zero bezel with substantially no bezel may be implemented.

In the non-display area NA of the display panel PN, a plurality of pad electrodes for transmitting various signals to the plurality of sub pixels SP may be disposed. For example, a first pad electrode PAD1 for transmitting a signal to the plurality of sub pixels SP may be disposed in the non-display area NA on the front surface of the display panel PN, and a second pad electrode PAD2 electrically connected to a driving component such as a flexible film and a printed circuit board may be disposed in the non-display area NA on the rear surface of the display panel PN.

In this case, although not illustrated in the drawings, various signal lines electrically connected to the plurality of sub pixels SP, for example, a scan line SL or a data line DL, may extend from the display area AA to the non-display area NA to be electrically connected to the first pad electrode PAD1.

Further, the side line SRL may be disposed along the side surface of the display panel PN. The side line SRL may electrically connect the first pad electrode PAD1 on the front surface of the display panel PN and the second pad electrode PAD2 on the rear surface of the display panel PN. Therefore, a signal from the driving component on the rear surface of the display panel PN may be transmitted to the plurality of sub pixels SP through the second pad electrode PAD2, the side line SRL, and the first pad electrode PAD1. Accordingly, a signal transmission path may be formed from the front surface to the side surface and the rear surface of the display panel PN to minimize or at least reduce an area of the non-display area NA on the front surface of the display panel PN.

Accordingly, the driving component may be electrically connected to the rear surface of the display panel PN using the side line SRL to reduce the area of the non-display area NA and implement the display device 100 with a minimized bezel. Further, when a plurality of display devices 100 with a minimized bezel is arranged to form a tiling display device, a seam area in which an image between the display devices 100 is not displayed may be minimized to improve display quality.

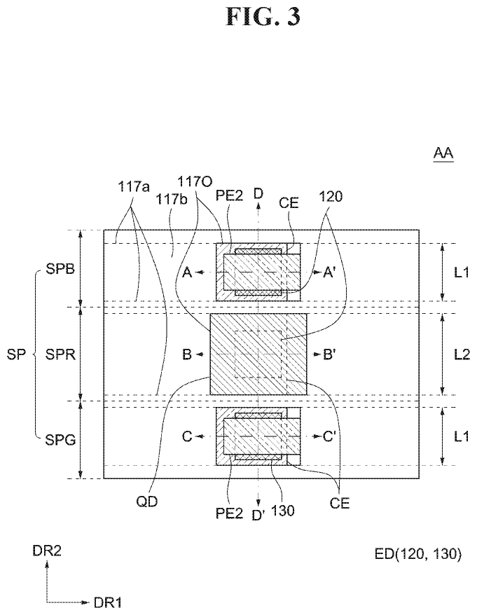

Hereinafter, a sub pixel SP of the display device 100 according to an embodiment of the invention will be described in more detail with reference to FIGS. 3 to 8.

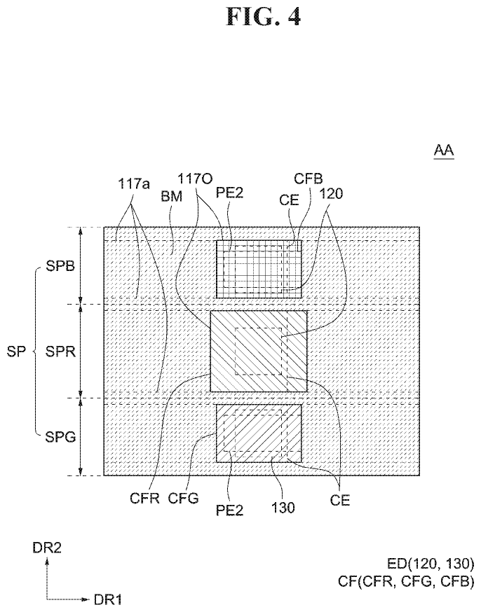

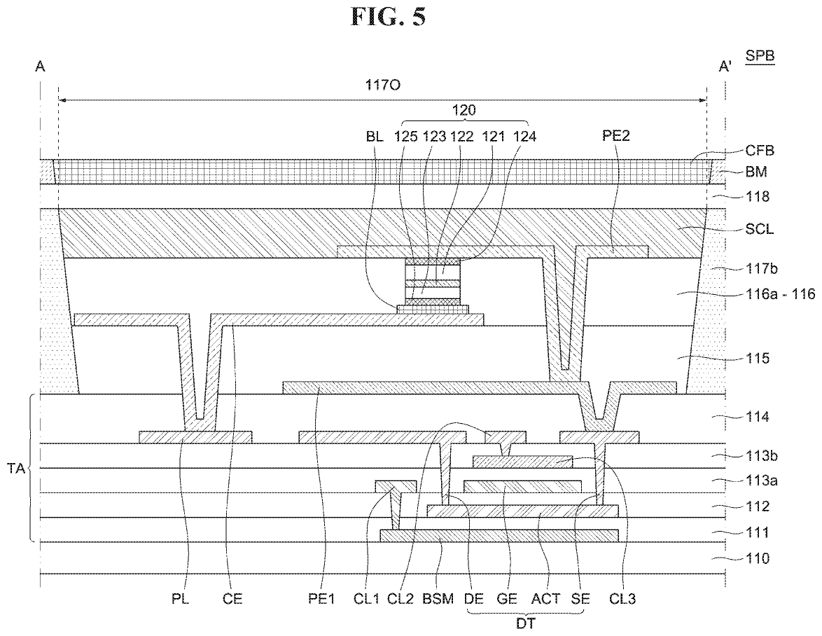

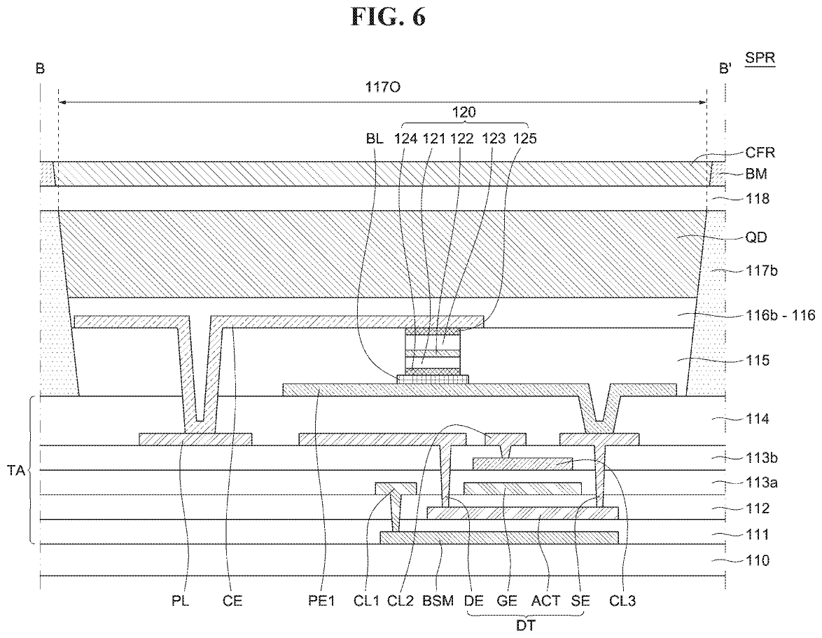

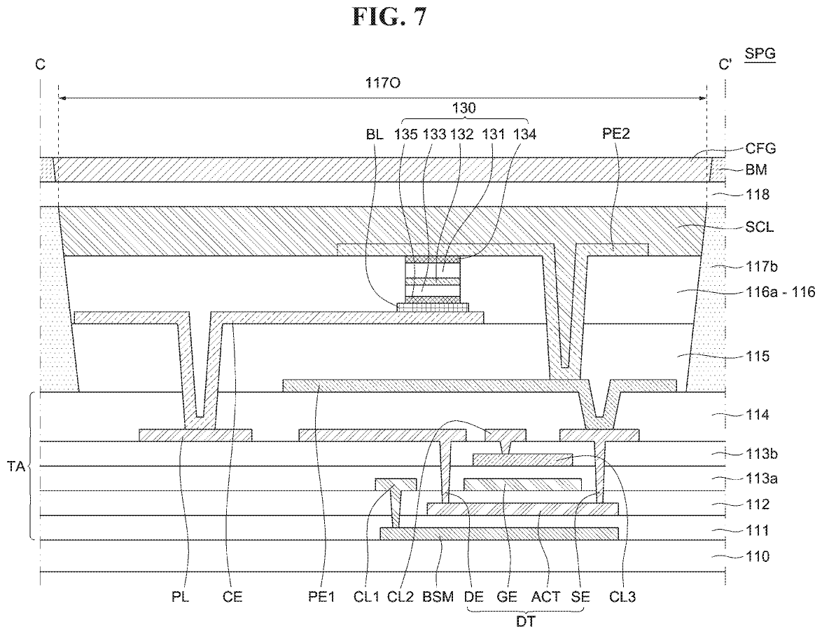

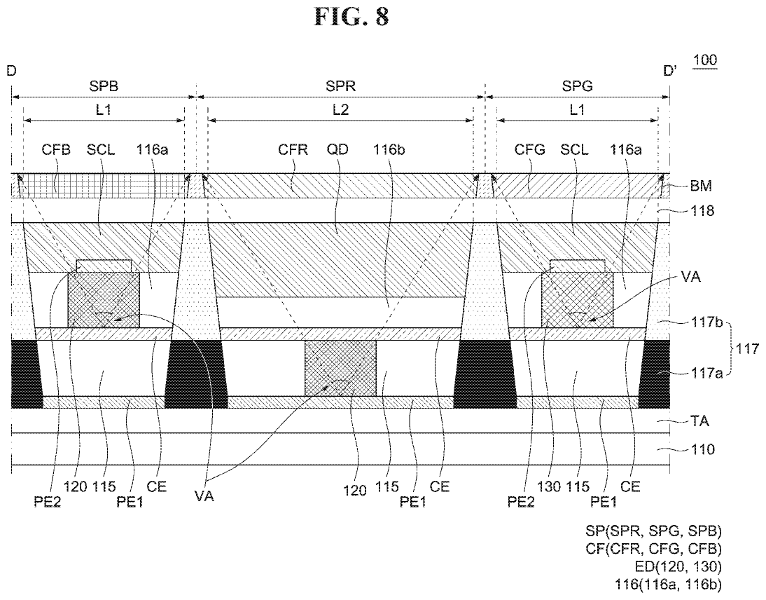

FIG. 3 is a schematic enlarged plan view of a display area of a display device according to an embodiment. FIG. 4 is a schematic enlarged plan view of a display area of a display device according to an embodiment. FIG. 5 is a cross-sectional view of a blue sub pixel taken along line A-A′ in FIG. 3. FIG. 6 is a cross-sectional view of a red sub pixel taken along line B-B′ in FIG. 3. FIG. 7 is a cross-sectional view of a green sub pixel taken along line C-C′ in FIG. 3. FIG. 8 is a schematic cross-sectional view of a plurality of sub pixels taken along line D-D′ in FIG. 3. For convenience of description, in FIG. 3, only a plurality of light emitting elements ED, a common electrode CE, a second pixel electrode PE2, a light conversion layer QD, a first bank 117a, and a second bank 117b are illustrated, and in FIG. 4, only a plurality of light emitting elements ED, a common electrode CE, a second pixel electrode PE2, a color filter CF, a first bank 117a, a second bank 117b, and a black matrix BM are illustrated, and in FIG. 8, only a TFT array TA and a light emitting element ED are schematically illustrated.

Referring to FIGS. 3 and 4, a plurality of sub pixels SP is disposed in the display area AA. Each of the plurality of sub pixels SP may include a light emitting element ED and independently emit light. The plurality of sub pixels SP may be arranged in a matrix while forming a plurality of rows and a plurality of columns, but embodiments of the invention are not limited thereto.

The plurality of sub pixels SP may include a red sub pixel SPR, a green sub pixel SPG, and a blue sub pixel SPB. Images of various colors may be displayed by a combination of red light, green light, and blue light from each of the red sub pixel SPR, the green sub pixel SPG, and the blue sub pixel SPB. For example, the blue sub pixel SPB, the red sub pixel SPR, and the green sub pixel SPG may be sequentially disposed along the second direction DR2.

In the figures, the blue sub pixel SPB, the red sub pixel SPR, and the green sub pixel SPG of the plurality of sub pixels SP are exemplarily illustrated as being arranged in the order along the second direction DR2. However, the inventive concepts are not limited to a particular arrangement of the plurality of sub pixels SP or a particular number of the sub pixels SP.

Next, referring to FIG. 5 together, a substrate 110 may be a member supporting other components of the display device 100. According to an embodiment, the substrate 110 may be an insulating substrate 110. For example, the substrate 110 may be made of glass, resin, or the like. According to another embodiment, the substrate 110 may be made of polymer, plastic, or the like. In some embodiments, the substrate 110 may be made of a plastic material having flexibility. A plurality of sub pixels SP may be formed on the substrate 110 to display an image.

A light shielding layer BSM may be disposed on the substrate 110 in each of the plurality of sub pixels SP. The light shielding layer BSM may block light incident on an active layer ACT of a driving transistor DT to minimize a leakage current. For example, the light shielding layer BSM may be disposed below the active layer ACT of the driving transistor DT to block light incident onto the active layer ACT. When light is incident on the active layer ACT, a leakage current may be generated to degrade the reliability of the driving transistor DT. Accordingly, the light shielding layer BSM for blocking light may be disposed on the substrate 110 to improve the reliability of the driving transistor DT. The light shielding layer BSM may be made of an opaque conductive material, such as copper (Cu), aluminum (Al), molybdenum (Mo), nickel (Ni), titanium (Ti), chromium (Cr), or an alloy thereof, but is not limited thereto.

A buffer layer 111 may be disposed on the substrate 110 and the light shielding layer BSM. The buffer layer 111 may cover one surface of the substrate 110 to reduce the penetration of moisture or impurities through the substrate 110. For example, the buffer layer 111 may be configured as a single layer or multilayer made of silicon oxide (SiOₓ) or silicon nitride (SiNₓ). However, the inventive concepts are not limited thereto. In some embodiments, the buffer layer 111 may be omitted depending on the type of substrate 110 or the type of transistor.

The driving transistor DT may be disposed on the buffer layer 111 in each of the plurality of sub pixels SP. The driving transistor DT may include an active layer ACT, a gate electrode GE, a source electrode SE, and a drain electrode DE. Although not illustrated in the drawings, other components, such as a switching transistor, a sensing transistor, an emission control transistor, and a storage capacitor, may be additionally disposed in each of the plurality of sub pixels SP, in addition to the driving transistor DT.

The active layer ACT of the driving transistor DT may be disposed on the buffer layer 111. The active layer ACT may be disposed to overlap the light shielding layer BSM. The active layer ACT may be formed of a semiconductor material such as an oxide semiconductor, amorphous silicon, or polysilicon, but is not limited thereto. Further, although not illustrated in the drawings, active layers ACT of other transistors, such as a switching transistor, a sensing transistor, and an emission control transistor, may also be formed of a semiconductor material, such as an oxide semiconductor, amorphous silicon, or polysilicon, without being limited thereto. In addition, the active layers ACT of the driving transistor DT, the switching transistor, the sensing transistor, and the emission control transistor may be formed of the same material or different materials.

A gate insulating layer 112 may be disposed on the active layer ACT. The gate insulating layer 112 may insulate the active layer ACT from the gate electrode GE. For example, the gate insulating layer 112 may be configured as a single layer or a double layer of silicon oxide (SiOₓ) or silicon nitride (SiNₓ), but is not limited thereto. Although the gate insulating layer 112 is exemplarily illustrated as being disposed on the entire surface of the substrate 110, in some embodiments, the gate insulating layer 112 may be disposed only below the gate electrode GE.

The gate electrode GE may be disposed on the gate insulating layer 112. The gate electrode GE may be disposed to overlap the active layer ACT. The gate electrode GE may include a conductive material such as copper (Cu), aluminum (Al), molybdenum (Mo), nickel (Ni), titanium (Ti), chromium (Cr), or an alloy thereof, but is not limited thereto.

A first interlayer insulating layer 113a and a second interlayer insulating layer 113b may be disposed on the gate electrode GE. In the first interlayer insulating layer 113a and the second interlayer insulating layer 113b, a contact hole may be respectively formed through which the source electrode SE and the drain electrode DE are electrically connected to the active layer ACT. The first interlayer insulating layer 113a and the second interlayer insulating layer 113b may protect components therebelow and may be configured as a single layer or a double layer of silicon oxide (SiOₓ) or silicon nitride (SiNₓ), but are not limited thereto.

The source electrode SE and the drain electrode DE may be disposed on the second interlayer insulating layer 113b. The source electrode SE and the drain electrode DE may be electrically connected to the active layer ACT through the contact holes formed in the first interlayer insulating layer 113a, the second interlayer insulating layer 113b, and the gate insulating layer 112. Any one of the source electrode SE and the drain electrode DE may be electrically connected to the light emitting element ED. For example, any one of the source electrode SE and the drain electrode DE may supply a driving current to the light emitting element ED. The source electrode SE and the drain electrode DE may include a conductive material, such as copper (Cu), aluminum (Al), molybdenum (Mo), nickel (Ni), titanium (Ti), chrome (Cr), or an alloy thereof, but are not limited thereto.

A first conductive layer CL1 may be disposed on the gate insulating layer 112. The first conductive layer CL1 may be an electrode for applying a constant voltage to the light shielding layer BSM and may be electrically connected to the light shielding layer BSM through contact holes formed in the gate insulating layer 112 and the buffer layer 111. For example, the light shielding layer BSM may be electrically connected to the first conductive layer CL1 such that the light shielding layer BSM does not operate as a floating gate, thereby preventing threshold voltage fluctuation of the driving transistor DT caused by the floating light shielding layer BSM. The first conductive layer CL1 may be formed of a conductive material, such as copper (Cu), aluminum (Al), molybdenum (Mo), nickel (Ni), titanium (Ti), chromium (Cr), or an alloy thereof, but is not limited thereto.

A second conductive layer CL2 may be disposed on the second interlayer insulating layer 113b, and a third conductive layer CL3 electrically connected to the second conductive layer CL2 may be disposed between the first interlayer insulating layer 113a and the second interlayer insulating layer 113b. The second conductive layer CL2 and the third conductive layer CL3 may overlap the gate electrode GE of the driving transistor DT to form a capacitor with the gate electrode GE of the driving transistor DT. Accordingly, various conductive layers, such as the second conductive layer CL2 and the third conductive layer CL3, may be disposed on the substrate 110 to form a capacitor. The second conductive layer CL2 and the third conductive layer CL3 may include a conductive material such as copper (Cu), aluminum (Al), molybdenum (Mo), nickel (Ni), titanium (Ti), chrome (Cr), or an alloy thereof, but are not limited thereto.

A power line PL may be disposed on the second interlayer insulating layer 113b. The power line PL may transmit a power voltage to the light emitting element ED of the plurality of sub pixels SP. The power line PL may be made of a conductive material, for example, copper (Cu), aluminum (Al), molybdenum (Mo), nickel (Ni), titanium (Ti), chromium (Cr), or an alloy thereof, but is not limited thereto. The power line PL may be configured as either a low potential power line or a high potential power line depending on the configuration of the pixel circuit.

A passivation layer 114 may be disposed on the driving transistor DT, the power line PL, and the second interlayer insulating layer 113b. The passivation layer 114 may planarize an upper portion of the pixel circuit including the driving transistor DT. The passivation layer 114 may be configured as a single layer or multilayer and made of, for example, any one of benzocyclobutene, an acrylic organic material, or an inorganic material such as silicon oxide (SiOₓ) or silicon nitride (SiNₓ), but is not limited thereto.

A portion in which a circuit for driving the sub pixel SP and a line are disposed, such as the driving transistor DT, the power line PL, and the plurality of conductive layers CL1, CL2, and CL3, may be defined as a TFT array TA. For example, components disposed in an area between the substrate 110 and the passivation layer 114 may be included in the TFT array TA. More particularly, the light shielding layer BSM, the driving transistor DT, the plurality of conductive layers, the power line PL, and the plurality of insulating layers disposed above and below these components may be referred to as a TFT array TA.

Referring to FIGS. 3, 4, and 8 together, the first bank 117a may be disposed between the plurality of sub pixels SP. The first bank 117a may be disposed between the plurality of sub pixels SP on the passivation layer 114. The first bank 117a may extend in the first direction DR1. For example, the first bank 117a extends in the first direction DR1 and may be disposed between the blue sub pixel SPB and the red sub pixel SPR, and between the red sub pixel SPR and the green sub pixel SPG. The first bank 117a may be disposed between the first planarization layer 115 of each of the plurality of sub pixels SP. The first bank 117a may minimize color mixture between the plurality of sub pixels SP and minimize cross talk due to color mixture.

The first bank 117a may be formed of an organic insulating material. For example, the first bank 117a may be formed of polyimide resin, acrylic resin, or benzocyclobutene (BCB) resin, but is not limited thereto. In some embodiments, the first bank 117a may include a black component having a high light absorption rate and may be configured as a black bank to suppress color mixture between adjacent sub pixels SP.

Next, referring to FIGS. 3, 5, and 8 together, the second bank 117b may be disposed on the first bank 117a and the passivation layer 114. The second bank 117b may be disposed to surround each of the plurality of sub pixels SP. The second bank 117b extends in the first direction DR1 and the second direction DR2 and may be disposed between the plurality of sub pixels SP. The second bank 117b may be disposed to surround the first planarization layer 115 of each of the plurality of sub pixels SP together with the first bank 117a. Further, the second bank 117b may be disposed to surround a second planarization layer 116, the light conversion layer QD, and a scattering layer SCL of each of the plurality of sub pixels SP. The second bank 117b surrounding the plurality of sub pixels SP in the first direction DR1 and the second direction DR2 may provide a space in which the light conversion layer QD and the scattering layer SCL may be disposed.

The second bank 117b includes a plurality of open areas 117O overlapping the light emitting elements ED of the plurality of sub pixels SP. Each of the plurality of open areas 117O may overlap a corresponding one of the plurality of light emitting elements ED. In this case, in the second direction DR2, a width of the open area 117O may correspond to a width of the sub pixel SP, which is defined by an interval between the first banks 117a. For example, the open area 117O overlapping the blue sub pixel SPB and the green sub pixel SPG may have a width of a first length L1 in the second direction DR2, and the open area 117O overlapping the red sub pixel SPR may have a width of a second length L2 in the second direction DR2.

The open area 117O overlapping the light emitting element ED may also be defined as an emission area. Further, the size of the open area 117O may be proportional to the size of the sub pixel SP.

The thickness of the second bank 117b may be substantially equal to the sum of the thickness of the first planarization layer 115, the thickness of the second planarization layer 116, and the thickness of the scattering layer SCL, or substantially equal to the sum of the thickness of the first planarization layer 115, the thickness of the second planarization layer 116, and the thickness of the light conversion layer QD. A thickness of the second bank 117b may be substantially equal to a sum of a thickness of the first planarization layer 115, a thickness of a 2-1-th planarization layer 116a, and a thickness of the scattering layer SCL in the blue sub pixel SPB and the green sub pixel SPG as shown in FIGS. 5 and 7, and may be substantially equal to a sum of a thickness of the first planarization layer 115, a thickness of a 2-2-th planarization layer 116b, and a thickness of the light conversion layer QD in the red sub pixel SPR as shown in FIG. 8.

The second bank 117b may be formed of an organic insulating material. For example, the second bank 117b may be formed of polyimide resin, acrylic resin, or benzocyclobutene (BCB) resin, but is not limited thereto.

According to an embodiment, the second bank 117b may be formed of an organic material having hydrophobic properties. Due to the hydrophobic properties of the second bank 117b, a material of the light conversion layer QD may be repelled from the second bank 117b and may be disposed in an area between the second banks 117b, that is, the open area 117O . Further, when forming the light conversion layer QD, a portion of the material forming the light conversion layer QD that is inadvertently applied onto the second bank 117b may flow down from the second bank 117b and be disposed in the open area 117O.

The size of the open area 117O of the second bank 117b may vary depending on the type of the plurality of sub pixels SP. For example, the open area 117O of each of the blue sub pixel SPB and the green sub pixel SPG may have a width in the second direction DR2 of a first length L1. Further, a width of the open area 117O of the red sub pixel SPR in the second direction DR2 may be a second length L2 greater than the first length L1.

More particularly, the width of the blue sub pixel SPB in the second direction DR2 and the width of the green sub pixel SPG in the second direction DR2 may be the first length L1, and the width of the red sub pixel SPR in the second direction DR2 may be the second length L2. In addition, the depth of the open area 117O in a thickness direction may be configured differently. For example, the open area 117O of each of the blue sub pixel SPB and the green sub pixel SPG may have a depth in the thickness direction that may be less than the depth of the open area 117O of the red sub pixel SPR.

Accordingly, the size of the open area 117O of the red sub pixel SPR may be larger than the size of the open area 117O of each of the green sub pixel SPG and the blue sub pixel SPB. The size of the open area 117O of the green sub pixel SPG may be substantially the same as the size of the open area 117O of the blue sub pixel SPB.

In the red sub pixel SPR, the light emitting element ED (120) may be disposed on the passivation layer 114 between the first pixel electrode PE1 and the common electrode CE. However, as the light emitting element ED (120 or 130) is disposed on the first planarization layer 115 over the common electrode CE in the blue sub pixel SPB and the green sub pixel SPG, the widths of the blue sub pixel SPB and the green sub pixel SPG may be formed to be narrower, which will be described in more detail below with reference to FIG. 8.

Referring to FIGS. 5 to 7 together, the first pixel electrode PE1 may be disposed on the passivation layer 114 in each of the plurality of sub pixels SP. The first pixel electrode PE1 may be disposed on a top surface of the passivation layer 114 exposed from the second bank 117b in the open area 117O. The first pixel electrode PE1 may be an electrode which electrically connects the light emitting element ED and the driving transistor DT. Further, the first pixel electrode PE1 may function as a reflection plate to reflect light emitted from the light emitting element ED in a direction toward the substrate 110 back to the top of the light emitting element ED. The first pixel electrode PE1 may overlap the light emitting element ED. Therefore, light emitted downwardly from the light emitting element ED may be reflected back by the first pixel electrode PE1 towards the top of the light emitting element ED to improve the light extraction efficiency.

The first pixel electrode PE1 may include various conductive layers in consideration of light reflection efficiency and resistance. For example, the first pixel electrode PE1 may include an opaque conductive layer such as silver (Ag), aluminum (Al), molybdenum (Mo), titanium (Ti), or an alloy thereof, or a transparent conductive layer such as indium tin oxide (ITO), but the configuration of the first pixel electrode PE1 is not limited thereto.

In each of the plurality of sub pixels SP, the first planarization layer 115 may be disposed on the first pixel electrode PE1. The first planarization layer 115 may cover the first pixel electrode PE1 in the open area 117O of the second bank 117b. In the red sub pixel SPR, the first planarization layer 115 may further cover or at least surround the light emitting element ED disposed between the first pixel electrode PE1 and the common electrode CE among the plurality of light emitting elements ED to fix and protect the light emitting element ED. Further, the first planarization layer 115 may be an insulating layer which separates the first pixel electrode PE1 from the common electrode CE. The first planarization layer 115 may be configured as a single layer or multilayer and be made of benzocyclobutene or an acrylic-based organic material, for example. However, the inventive concepts are not limited thereto.

In each of the plurality of sub pixels SP, the common electrode CE may be disposed on the first planarization layer 115. The common electrode CE may be an electrode which electrically connects the power line PL and the plurality of light emitting elements ED. The common electrode CE may be electrically connected to the power line PL through contact holes formed in the first planarization layer 115 and the passivation layer 114. Further, the common electrode CE may be electrically connected to the n-type electrode of the light emitting element ED. The common electrode CE may be made of a transparent conductive material to transmit light emitted from the light emitting element ED. For example, the common electrode CE may be formed of a transparent conductive material such as indium tin oxide (ITO) or indium zinc oxide (IZO).

The second planarization layer 116 may be disposed on the common electrode CE in each of the plurality of sub pixels SP. The second planarization layer 116 may be disposed in the open area 117O of the second bank 117b to cover the common electrode CE and the first planarization layer 115. The second planarization layer 116 may cover the light emitting element ED disposed between the common electrode CE and the second pixel electrode PE2, among the plurality of light emitting elements ED, and fix and protect the light emitting element ED. The second planarization layer 116 may be an insulating layer that separates the second pixel electrode PE2 and the common electrode CE. The second planarization layer 116 may be configured as a single layer or multilayer and be made of benzocyclobutene or an acrylic-based organic material, for example. However, the inventive concepts are not limited thereto.

The second planarization layer 116 may include a 2-1-th planarization layer 116a and a 2-2-th planarization layer 116 b. The 2-1-th planarization layer 116a may be disposed in the blue sub pixel SPB and the green sub pixel SPG, and the 2-2-th planarization layer 116b may be disposed in the red sub pixel SPR. A thickness of the 2-1-th planarization layer 116a may be greater than a thickness of the 2-2-th planarization layer 116b.

In the red sub pixel SPR, the light emitting element ED (120) may be disposed between the first pixel electrode PE1 and the common electrode CE. More particularly, in the red sub pixel SPR, the light emitting element ED may not be disposed above the common electrode CE. Therefore, the 2-2-th planarization layer 116 b may be formed to be thinner than the light emitting element ED, or the 2-2-th planarization layer 116 b may be omitted in some embodiments. In addition, in the red sub pixel SPR, the light conversion layer QD may be formed, and the light conversion layer QD may have a thickness equal to or greater than a predetermined thickness to secure light conversion efficiency. Further, the light conversion layer QD may be filled in the remaining space of the open area 117O that is not occupied by the first planarization layer 115 and the 2-2 planarization layer 116b. Therefore, in the red sub pixel SPR, by minimizing the thickness of the 2-2-th planarization layer 116 b, a depth of the remaining space of the open area 117O filled with the light conversion layer QD may be increased, thereby improving the light conversion efficiency.

In contrast, in the blue sub pixel SPB and the green sub pixel SPG, the light emitting element ED may be disposed between the common electrode CE and the second pixel electrode PE2. Therefore, the 2-1-th planarization layer 116a may be formed to be thicker than the 2-2-th planarization layer 116b so that the 2-1-th planarization layer 116a may cover or at least surround the n-type semiconductor layer, the emission layer, and the p-type semiconductor layer of the light emitting element ED to prevent a short defect. Further, since the light conversion layer QD may not be disposed in the blue sub pixel SPB and the green sub pixel SPG, the thickness of the 2-1-th planarization layer 116a is not limited by the light conversion layer QD.

Next, referring to FIGS. 5 and 7, in the blue sub pixel SPB and the green sub pixel SPG among the plurality of sub pixels SP, the second pixel electrode PE2 may be disposed on the second planarization layer 116. The second pixel electrode PE2 may be an electrode which electrically connects the light emitting element ED and the driving transistor DT. The second pixel electrode PE2 may be electrically connected to the first pixel electrode PE1 through contact holes formed in the first planarization layer 115 and the second planarization layer 116. Therefore, the second pixel electrode PE2 may be electrically connected to the driving transistor DT through the first pixel electrode PE1. The second pixel electrode PE2 may be made of a transparent conductive material to transmit light emitted from the light emitting element ED. For example, the second pixel electrode PE2 may be formed of a transparent conductive material such as indium tin oxide (ITO) or indium zinc oxide (IZO).

Referring to FIG. 5, the blue sub pixel SPB may include a first light emitting element 120 that emits blue light to display blue light.

In the blue sub pixel SPB, the bonding layer BL may be disposed on the common electrode CE. The bonding layer BL may be a conductive bonding member for connecting the light emitting element ED to the common electrode CE. The bonding layer BL may have conductivity to electrically connect the common electrode CE and the light emitting element ED. The bonding layer BL may have adhesiveness to fix the light emitting element ED to the common electrode CE. For example, the bonding layer BL may be an organic layer including conductive particles such as indium (In) or carbon, or a solder pattern including indium (In), tin (Sn), or an alloy thereof, but is not limited thereto.

Each of the plurality of light emitting elements ED is disposed in each of the plurality of sub pixels SP. The plurality of light emitting elements ED may be one of a light emitting diode (LED) or a micro light emitting diode (micro LED). The plurality of light emitting elements ED may include a first light emitting element 120 and a second light emitting element 130. The first light emitting element 120 may be a blue light emitting element ED that emits blue light, and the second light emitting element 130 may be a green light emitting element ED that emits green light.

The first light emitting element 120 may be disposed on the bonding layer BL in the blue sub pixel SPB. The first light emitting element 120 may include a first n-type semiconductor layer 123, a first emission layer 122, a first p-type semiconductor layer 121, a first n-type electrode 125, and a first p-type electrode 124.

The first n-type semiconductor layer 123 may be disposed on the bonding layer BL, and the first p-type semiconductor layer 121 may be disposed on the first n-type semiconductor layer 123. Each of the first p-type semiconductor layer 121 and the first n-type semiconductor layer 123 may be a semiconductor layer doped with p-type and n-type impurities, respectively. For example, the first p-type semiconductor layer 121 and the first n-type semiconductor layer 123 may be layers respectively doped with p-type and n-type impurities into a material such as gallium nitride (GaN), indium aluminum phosphide (InAlP), or gallium arsenide (GaAs). The p-type impurity may include magnesium (Mg), zinc (Zn), beryllium (Be), and the like, and the n-type impurity may include silicon (Si), germanium(Ge), tin (Sn), and the like, but are not limited thereto.

The first emission layer 122 may be disposed between the first p-type semiconductor layer 121 and the first n-type semiconductor layer 123. The first emission layer 122 may emit light based on a driving current supplied to the first light emitting element 120. For example, the first emission layer 122 may emit blue light. The first emission layer 122 may be formed as a single layer or to have a multi-quantum well (MQW) structure, and for example, may be formed of indium gallium nitride (InGaN) or gallium nitride (GaN), but is not limited thereto.

The first n-type electrode 125 may be disposed between the first n-type semiconductor layer 123 and the bonding layer BL. The first n-type electrode 125 may be in contact with the lower surface of the first n-type semiconductor layer 123. The first n-type electrode 125 may be an electrode for electrically connecting the first light emitting element 120 to the common electrode CE and the power line PL. The first light emitting element 120 may be electrically connected to the power line PL through the first n-type electrode 125 and the common electrode CE. The first n-type electrode 125 may be formed of a transparent conductive material, such as indium tin oxide (ITO) or indium zinc oxide (IZO), but is not limited thereto.

The first p-type electrode 124 may be disposed between the first p-type semiconductor layer 121 and the second pixel electrode PE2. The first p-type electrode 124 may be in contact with the top surface of the first p-type semiconductor layer 121. The first p-type electrode 124 may be an electrode for electrically connecting the first light emitting element 120 to the driving transistor DT. The first light emitting element 120 may be electrically connected to the driving transistor DT through the first p-type electrode 124, the second pixel electrode PE2, and the first pixel electrode PE1. The first p-type electrode 124 may be formed of a transparent conductive material, such as indium tin oxide (ITO) or indium zinc oxide (IZO), but is not limited thereto.

Although not illustrated in the drawings, a protective layer may be further disposed to surround the first n-type semiconductor layer 123, the first emission layer 122, and the first p-type semiconductor layer 121. The protective layer may protect the first n-type semiconductor layer 123, the first emission layer 122, and the first p-type semiconductor layer 121. For example, the protective layer may be formed of an insulating material such as silicon oxide (SiOₓ) or silicon nitride (SiNₓ), but is not limited thereto.

In the blue sub pixel SPB, blue light emitted from the first light emitting element 120, which is the blue light emitting element ED, may pass through the blue color filter CFB without conversion and be emitted to the outside of the display device 100. Accordingly, in the blue sub pixel SPB, since a space for disposing the light conversion layer QD on the blue light emitting element ED may be obviated, the blue light emitting element ED may be disposed on the first planarization layer 115, and the 2-1-th planarization layer 116 a may be formed to have a thickness covering or at least surrounding the first n-type semiconductor layer 123, the first emission layer 122, and the first p-type semiconductor layer 121 of the blue light emitting element ED.

In the blue sub pixel SPB, the scattering layer SCL may be disposed on the second pixel electrode PE2. The scattering layer SCL may scatter light emitted from the first light emitting element 120 to improve the viewing angle of the blue sub pixel SPB. The scattering layer SCL may include a plurality of light scattering materials such as titanium dioxide (TiO₂). Therefore, at least a part of the light emitted from the first light emitting element 120 may be reflected and scattered by the scattering layer SCL and spread, thereby further improving the viewing angle of the blue sub pixel SPB.

Referring to FIG. 6, the red sub pixel SPR may include a first light emitting element 120 which emits blue light and a light conversion layer QD to display red light.

In the red sub pixel SPR, the bonding layer BL may be disposed on the first pixel electrode PE1, and the first light emitting element 120 may be disposed between the bonding layer BL and the common electrode CE. Since the thickness of the 2-2-th planarization layer 116b may be formed thin in consideration of the light conversion layer QD disposed thereon, the first light emitting element 120 may be disposed on the first planarization layer 115 which may cover or at least surround the first n-type semiconductor layer 123, the first emission layer 122, and the first p-type semiconductor layer 121 of the first light emitting element 120. More particularly, the first light emitting element 120 may be surrounded by the first planarization layer 115 between the first pixel electrode PE1 and the common electrode CE.

In this case, the first light emitting element 120 may be arranged such that the first n-type electrode 125 of the first light emitting element 120 is connected to the common electrode CE. More particularly, in the blue sub pixel SPB, the first n-type electrode 125 of the first light emitting element 120 may face downward, while in the red sub pixel SPR, the first n-type electrode 125 of the first light emitting element 120 may be face upward. The first light emitting element 120 of the blue sub pixel SPB and the first light emitting element 120 of the red sub pixel SPR may be disposed in opposite directions, up and down, or stacked in the reverse order, with respect to the common electrode CE.

Further, in the red sub pixel SPR, the first light emitting element 120 may be covered or at least be surrounded by the first planarization layer 115 instead of the 2-2-th planarization layer 116b to protect the first light emitting element 120. Accordingly, the thickness of the 2-2-th planarization layer 116 b may be minimized.

In the red sub pixel SPR, the light conversion layer QD may be disposed on the 2-2-th planarization layer 116b. The light conversion layer QD may include a light conversion material such as a quantum dot, a nano phosphor, or an organic phosphor to convert light emitted from the first light emitting element 120 into light of various colors. For example, the light conversion layer QD may convert blue light emitted from the first light emitting element 120 into red light. In general, a conventional red light emitting element ED has a problem in that the luminous efficiency is lower than that of the blue first light emitting element 120. Therefore, in the red sub pixel SPR according to an embodiment, the blue first light emitting element 120 with high luminous efficiency and the red light conversion layer QD may be disposed to increase the red light efficiency.

Since the thickness of the 2-2-th planarization layer 116b of the red sub pixel SPR may be less than the thickness of the 2-1-th planarization layer 116a of the blue sub pixel SPB and the green sub pixel SPG, the thickness of the light conversion layer QD may be greater than the thickness of the scattering layer SCL.

Referring to FIG. 7, the green sub pixel SPG may include the second light emitting element 130 emitting green light to display green light.

The bonding layer BL may be disposed on the common electrode CE, and the second light emitting element 130 may be disposed between the bonding layer BL and the second pixel electrode PE2. The second light emitting element 130 may include a second n-type semiconductor layer 133, a second emission layer 132, a second p-type semiconductor layer 131, a second n-type electrode 135, and a second p-type electrode 134.

The second n-type semiconductor layer 133 may be disposed on the bonding layer BL, and the second p-type semiconductor layer 131 may be disposed on the second n-type semiconductor layer 133. Each of the second p-type semiconductor layer 131 and the second n-type semiconductor layer 133 may be a semiconductor layer respectively doped with p-type and n-type impurities. For example, the second p-type semiconductor layer 131 and the second n-type semiconductor layer 133 may be layers respectively doped with p-type and n-type impurities into a material such as gallium nitride (GaN), indium aluminum phosphide (InAlP), or gallium arsenide (GaAs). The p-type impurity may be magnesium (Mg), zinc (Zn), beryllium (Be), and the like, and the n-type impurity may be silicon (Si), germanium(Ge), tin (Sn), and the like, but are not limited thereto.

The second emission layer 132 may be disposed between the second p-type semiconductor layer 131 and the second n-type semiconductor layer 133. The second emission layer 132 may emit light based on a driving current supplied to the second light emitting element 130. For example, the second emission layer 132 may emit green light. The second emission layer 132 may be formed as a single layer or to have a multi-quantum well (MQW) structure, and for example, may be formed of indium gallium nitride (InGaN) or gallium nitride (GaN), but is not limited thereto.

The second n-type electrode 135 may be disposed between the second n-type semiconductor layer 133 and the bonding layer BL. The second n-type electrode 135 may be in contact with the lower surface of the second n-type semiconductor layer 133. The second n-type electrode 135 may be an electrode which electrically connects the second light emitting element 130 to the common electrode CE and the power line PL. The second light emitting element 130 may be electrically connected to the power line PL through the second n-type electrode 135 and the common electrode CE. The second n-type electrode 135 may be formed of a transparent conductive material, such as indium tin oxide (ITO) or indium zinc oxide (IZO), but is not limited thereto.

The second p-type electrode 134 may be disposed between the second p-type semiconductor layer 131 and the second pixel electrode PE2. The second p-type electrode 134 may be in contact with the top surface of the second p-type semiconductor layer 131. The second p-type electrode 134 may be an electrode which electrically connects the second light emitting element 130 to the driving transistor DT. The second light emitting element 130 may be electrically connected to the driving transistor DT through the second p-type electrode 134, the second pixel electrode PE2, and the first pixel electrode PE1. The second p-type electrode 134 may be formed of a transparent conductive material, such as indium tin oxide (ITO) or indium zinc oxide (IZO), but is not limited thereto.

Although not illustrated in the drawings, a protective layer may be further disposed to surround the second n-type semiconductor layer 133, the second emission layer 132, and the second p-type semiconductor layer 131. The protective layer may protect the second n-type semiconductor layer 133, the second emission layer 132, and the second p-type semiconductor layer 131. For example, the protective layer may be formed of an insulating material such as silicon oxide (SiOₓ) or silicon nitride (SiNₓ), but is not limited thereto.

In the green sub pixel SPG, green light emitted from the second light emitting element 130, which is the green light emitting element ED, may pass through the green color filter CFG without conversion and be emitted to the outside of the display device 100. In the green sub pixel SPG, since a space for disposing the light conversion layer QD on the second light emitting element 130 emitting green light may be obviated, the second light emitting element 130 may be disposed on the first planarization layer 115, and the 2-1-th planarization layer 116a may be formed to have a thickness covering or at least surrounding the second n-type semiconductor layer 133, the second emission layer 132, and the second p-type semiconductor layer 131 of the second light emitting element 130.

In the green sub pixel SPG, the scattering layer SCL may be disposed on the second pixel electrode PE2 in the same manner as in the blue sub pixel SPB. The scattering layer SCL may scatter light emitted from the second light emitting element 130 to improve the viewing angle of the green sub pixel SPG. At least a part of the light emitted from the second light emitting element 130 may be reflected and scattered by the scattering layer SCL and spread, thereby further improving the viewing angle of the green sub pixel SPG.

Next, referring to FIGS. 5 to 8, the protective layer 118 may be disposed on the scattering layer SCL, the light conversion layer QD, and the second bank 117b. The protective layer 118 may protect the scattering layer SCL and the light conversion layer QD of the plurality of sub pixels SP. The protective layer 118 may provide a flat surface on the scattering layer SCL, the light conversion layer QD, and the second bank 117b. The protective layer 118 may be formed of either an organic insulating material or an inorganic insulating material.

A plurality of color filters CF may be disposed on the protective layer 118. The plurality of color filters CF may overlap the plurality of sub pixels SP. The plurality of color filters CF may include a red color filter CFR, a green color filter CFG, and a blue color filter CFB. The red color filter CFR may overlap the red sub pixel SPR, the green color filter CFG may overlap the green sub pixel SPG, and the blue color filter CFB may overlap the blue sub pixel SPB. Blue light and green light emitted from the plurality of light emitting elements ED and red light converted from the light conversion layer QD may pass through the blue color filter CFB, the green color filter CFG, and the red color filter CFR, respectively, and may travel to the outside of the display device 100. On the other hand, external light incident on the display device 100 may be absorbed by the plurality of color filters CF and not reflected back to the outside of the display device 100. Therefore, by providing the color filter CF which absorbs external light and transmits red light converted by the light conversion layer QD, and green light and blue light emitted from the light emitting element ED, the display quality and the color reproducibility may be improved.

A black matrix BM may be disposed on the protective layer 118. The black matrix BM may be disposed between the plurality of color filters CF. The black matrix BM may shield light of each of the plurality of sub pixels SP to prevent the light from being mixed with one another. In addition, the black matrix BM may absorb light incident from the outside to the display device 100, thereby minimizing a decrease in visibility due to the reflection of external light from the configuration inside the display device 100. For example, the black matrix BM may include a black component and be made of an opaque resin including a pigment, but is not limited thereto.

The black matrix BM may overlap the second bank 117b. The black matrix BM may include an opening having the substantially same size and shape as the open area 117O of the second bank 117b, and each of the plurality of color filters CF may be disposed in the opening of the black matrix BM. The opening of the black matrix BM and the opening of the second bank 117b may correspond to the emission area of each of the plurality of sub pixels SP.

Referring to FIGS. 3 and 8 together, in the display device 100 according to an embodiment of the invention, in the sub pixel SP in which the light conversion layer QD is not disposed, the light emitting element ED is disposed on the common electrode CE to reduce the width of the sub pixel SP while maintaining the viewing angle. Further, in the display device 100 according to an embodiment of the invention, in the sub pixel SP in which the light conversion layer QD is disposed, the light emitting element ED is disposed below the common electrode CE to minimize the thickness of the 2-2-th planarization layer 116b between the common electrode CE and the light conversion layer QD, thereby increasing the light conversion efficiency by narrowing the gap between the light emitting element ED and the light conversion layer QD.

More particularly, in the red sub pixel SPR in which the light conversion layer QD is disposed, the first light emitting element 120 may be disposed below the common electrode CE. Therefore, in the red sub pixel SPR, the first light emitting element 120 is not disposed above the first planarization layer 115, that is, on the common electrode CE, so that the second pixel electrode PE2 may be omitted. In addition, since the first light emitting element 120 of the red sub pixel SPR is not disposed above the common electrode CE, the 2-2-th planarization layer 116b may not require a thickness for covering or at least surrounding the first light emitting element 120. As such, the 2-2-th planarization layer 116b disposed on the first planarization layer 115 may be formed to be thinner than the 2-1-th planarization layer 116a. Accordingly, in the red sub pixel SPR, the first light emitting element 120 and the light conversion layer QD may be disposed closer due to the relatively thin thickness of the 2-2-th planarization layer 116b interposed therebetween, thereby improving the light conversion efficiency of the light conversion layer QD.

If the 2-2-th planarization layer 116b of the red sub pixel SPR has the same thickness as the 2-1-th planarization layer 116 a, the depth of a space in which the light conversion layer QD is to be formed becomes shallow, so the light conversion layer QD may bno have a sufficient thickness. In addition, as the distance between the first light emitting element 120 and the light conversion layer QD increases, the light conversion efficiency of the light conversion layer QD may be degraded.

Further, the first light emitting element 120 which emits blue light is disposed in the blue sub pixel SPB and the second light emitting element 130 which emits green light is disposed in the green sub pixel SPG, the light conversion layer QD may be obviated in the blue sub pixel SPB and the green sub pixel SPG. Therefore, since the blue sub pixel SPB and the green sub pixel SPG may not be limited to the thickness of the light conversion layer QD, the plurality of light emitting elements ED and the second pixel electrode PE2 may be easily disposed on the common electrode CE.

In this case, even though the width of the open area 117O in each of the blue sub pixel SPB and the green sub pixel SPG is formed to be narrower than that in the red sub pixel SPR, the viewing angle of the light emitted from each of the light emitting elements ED may be formed to be substantially the same. For example, in the red sub pixel SPR in which the first light emitting element 120 is disposed below the common electrode CE, the width of the open area 117O of the second bank 117b may be designed to be the second length L2 so that light emitted from the first light emitting element 120 is emitted within a range of the first viewing angle VA, and the opening of the black matrix BM may also be formed to have a size and a position corresponding to the open area 117O. As another example, the widths of the emission areas of the blue sub pixel SPB and the green sub pixel SPG in the second direction DR2 may be designed to have the first length L1.

Further, the light emitting elements ED of the blue sub pixel SPB and the green sub pixel SPG may be disposed on the common electrode CE and disposed at a higher elevation than the light emitting elements ED of the red sub pixel SPR. The light emitting element ED of the blue sub pixel SPB and the green sub pixel SPG may be disposed relatively closer to the upper end of the second bank 117b than the light emitting elements ED of the red sub pixel SPR. As the light emitting element ED is disposed closer to the upper end of the second bank 117b, less light is blocked by the second bank 117b and the black matrix BM, and more light is directed to the outside through the openings of the open area 117O of the second bank 117b and the black matrix BM. More particularly, as the light emitting element ED is disposed closer to the upper end of the second bank 117b, the range of viewing angle over which light from the light emitting element ED is emitted may increase, whereas as the distance from the upper end of the second bank 117b increases, the viewing angle range may decrease.

Further, as the width of the open area 117O of the second bank 117b decreases, a greater amount of light may be blocked by the second bank 117b and the black matrix BM, and a range of viewing angle over which light emitted from the light emitting element ED is emitted may decrease. As the width of the open area 117O of the second bank 117b increases, a greater amount of light may be directed to the outside through the openings of the open area 117O and the black matrix BM of the second bank 117b, and the range of a viewing angle range over which light emitted from the light emitting element ED is emitted may increase.

Accordingly, in the blue sub pixel SPB and the green sub pixel SPG, in which the light emitting element ED is disposed relatively closer to the upper end of the second bank 117b, the width of the open area 117O may be reduced such that a viewing angle range in which light emitted from the light emitting element ED is emitted may have substantially the same first viewing angle VA as the red sub pixel SPR.

Accordingly, in the display device 100 according to an embodiment of the invention, the width of the open area 117O is configured to be different in consideration of the placement elevation of the light emitting element ED in each of the plurality of sub pixels SP, so that the viewing angle of each of the plurality of sub pixels SP may become substantially the same. In addition, in the blue sub pixel SPB and the green sub pixel SPG in which the light conversion layer QD is not disposed, the light emitting element ED may be disposed closer to the upper end of the second bank 117b to reduce the size of the blue sub pixel SPB and the green sub pixel SPG and implement a high-resolution display device 100.

According to embodiments of the invention, the size of at least some of the plurality of sub pixels may be reduced, thereby providing a high-resolution display device.

According to embodiments of the invention, it is possible to increase the light conversion efficiency by arranging the light conversion layer and the light emitting element close together.

According to embodiments of the invention, a space for forming a light conversion layer having an appropriate thickness may be secured by minimizing the thickness of the second planarization layer in the red sub pixel.

According to embodiments of the invention, viewing angles of a plurality of sub pixels having different sizes may be configured to be substantially the same.

According to embodiments of the invention, the viewing angle may be adjusted by disposing the scattering layer.

Although certain embodiments and implementations have been described herein, other embodiments and modifications will be apparent from this description. Accordingly, the inventive concepts are not limited to such embodiments, but rather to the broader scope of the appended claims and various obvious modifications and equivalent arrangements as would be apparent to a person of ordinary skill in the art.

What is claimed is:

1. A display device, comprising:
a substrate on which a plurality of sub pixels including a red sub pixel, a green sub pixel, and a blue sub pixel is defined;
a TFT array disposed on the substrate;
a plurality of light emitting elements disposed on the TFT array in each of the plurality of sub pixels; and
a bank disposed between the plurality of sub pixels and including a plurality of open areas overlapping the plurality of light emitting elements,
wherein a light emitting element of the red sub pixel among the plurality of light emitting elements is disposed at a lower elevation than light emitting elements of the green sub pixel and the blue sub pixel, and
wherein a size of an open area of the red sub pixel among the plurality of open areas is greater than a size of an open area of each of the green sub pixel and the blue sub pixel.

2. The display device according to claim 1, wherein the size of the open area of the green sub pixel and the size of the open area of the blue sub pixel are substantially the same.

3. The display device according to claim 1, wherein the plurality of light emitting elements includes:
a first light emitting element disposed in the red sub pixel and the blue sub pixel and configured to emit blue light; and
a second light emitting element disposed in the green sub pixel and configured to emit green light.

4. The display device according to claim 3, further comprising:
a first pixel electrode disposed between the TFT array and the plurality of light emitting elements in each of the plurality of sub pixels;
a first planarization layer disposed on the first pixel electrode;
a common electrode disposed on the first planarization layer in each of the plurality of sub pixels;
a second planarization layer disposed on the common electrode; and
a second pixel electrode disposed on the second planarization layer in the green sub pixel and the blue sub pixel.

5. The display device of claim 4, wherein in the red sub pixel, the first light emitting element is disposed between the first pixel electrode and the common electrode, and is surrounded by the first planarization layer.

6. The display device of claim 5, wherein each of the second light emitting element of the green sub pixel and the first light emitting element of the blue sub pixel is disposed between the common electrode and the second pixel electrode, and is surrounded by the second planarization layer.

7. The display device of claim 6, wherein each of the second light emitting element of the green sub pixel and the first light emitting element of the blue sub pixel is disposed at a higher elevation than the first light emitting element of the red sub pixel, and is disposed closer to an upper end of the bank.

8. The display device according to claim 7, wherein a range of a viewing angle over which light is emitted from each of the first light emitting element of the red sub pixel, the second light emitting element of the green sub pixel, and the first light emitting element of the blue sub pixel is substantially the same.

9. The display device of claim 6, wherein the first light emitting element includes:
a first n-type electrode;
a first n-type semiconductor layer on one surface of the first n-type electrode;
a first emission layer on one surface of the first n-type semiconductor layer;
a first p-type semiconductor layer on one surface of the first emission layer; and
a first p-type electrode on one surface of the first p-type semiconductor layer, and
wherein the first n-type electrode of the first light emitting element of the red sub pixel is electrically connected to the common electrode, and the first p-type electrode of the first light emitting element of the red sub pixel is electrically connected to the first pixel electrode, and
wherein the first n-type electrode of the first light emitting element of the blue sub pixel is electrically connected to the common electrode, and the first p-type electrode of the first light emitting element of the blue sub pixel is electrically connected to the second pixel electrode.

10. The display device of claim 9, wherein the first n-type electrode, the first n-type semiconductor layer, the first emission layer, the first p-type semiconductor layer, and the first p-type electrode in the red sub pixel are stacked in a reverse order from those in the blue sub pixel.

11. The display device of claim 6, further comprising:
a light conversion layer disposed on the second planarization layer in the red sub pixel; and
a scattering layer disposed on the second planarization layer in the green sub pixel and the blue sub pixel.

12. The display device according to claim 11, wherein the second planarization layer includes:
a 2-1-th planarization layer disposed in the green sub pixel and the blue sub pixel; and
a 2-2-th planarization layer disposed in the red sub pixel, and
wherein a thickness of the 2-1-th planarization layer is greater than a thickness of the 2-2-th planarization layer.

13. The display device according to claim 11, wherein the light conversion layer and the scattering layer are disposed in a space between the banks, and
wherein a thickness of the light conversion layer is greater than a thickness of the scattering layer.

14. The display device according to claim 11, wherein the bank includes:
a first bank extending in a first direction between the plurality of sub pixels; and
a second bank disposed on the first bank and the TFT array and extending between the plurality of sub pixels in the first direction and a second direction different from the first direction,
wherein the first bank is disposed between the first planarization layers of the plurality of sub pixels, and
wherein the second bank is disposed to surround the first planarization layer, the second planarization layer, the light conversion layer, and the scattering layer of the plurality of sub pixels.

15. A display device, comprising:
a first sub pixel, a second sub pixel, and a third sub pixel configured to emit light of a different color and each including a light emitting element;
a first electrode disposed on the light emitting elements of the first, second, and third sub pixels;
a planarization layer disposed on the first electrode,
wherein a thickness of the planarization layer disposed in the second sub pixel is less than that of the planarization layer disposed in the first and third sub pixels, and
wherein a width of the planarization layer disposed in the second sub pixel is greater than that of the planarization layer disposed in the first and third sub pixels.

16. The display device according to claim 15, wherein the planarization layer of the second sub pixel is spaced apart from the light emitting element of the second sub pixel, and the planarization layer of the first sub pixel is disposed on a same plane as the light emitting element of the first sub pixel.

17. The display device according to claim 15, wherein the light emitting elements of the first and second sub pixels are respectively disposed on opposing surfaces of the first electrode.

18. The display device according to claim 15, further comprising a light conversion layer disposed on the planarization layer of the second sub pixel,
wherein the light conversion layer has a thickness greater than that of the planarization layer of the first sub pixel.
